(19) United States
(12) Patent Application Publication
(10) Pub. No.: US 2024/0363455 A1
(43) Pub. Date: Oct. 31, 2024

(54) THIN FILM PEELING TEST STRUCTURE AND THIN FILM PEELING TEST METHOD USING THE SAME

(71) Applicant: SK hynix system ic (Wuxi) Co., Ltd., Jiangsu Province (CN)

(72) Inventor: Kyung Wook KWON, Gyeonggi-do (KR)

(21) Appl. No.: 18/496,917

(22) Filed: Oct. 30, 2023

(30) Foreign Application Priority Data
Apr. 28, 2023 (KR) 10-2023-0056671

(51) Int. Cl. H01L 21/66

(52) U.S. Cl. CPC H01L 22/34; H01L 22/14; H01L 22/32

(57) ABSTRACT

A thin film peeling test structure according to an embodiment of the present disclosure includes a peeling risk layer disposed on a substrate, a peeling test layer disposed on the peeling risk layer, a planarized insulation layer disposed on the peeling test layer, first and second via holes penetrating the planarized insulation layer and reaching inside the peeling test layer, first and second contact vias disposed in the first and second via holes, respectively, and first and second test pads electrically connected to the first and second contact vias, respectively.

### CROSS-REFERENCE TO RELATED APPLICATIONS

The present application claims priority under 35 U.S.C. 119(a) to Korean Patent Application No. 10-2023-0056671, filed on Apr. 28, 2023, which is incorporated herein by reference in its entirety.

### BACKGROUND

### 1. Technical Field

Embodiments of the present disclosure generally relate to a thin film peeling test method and, more particularly, to a thin film peeling test structure and a thin film peeling test method using the same.

### 2. Related Art

When an integrated circuit is manufactured on a substrate through a semiconductor process, different types of thin films may be sequentially stacked on the substrate. In this case, when a pair of thin films in contact with each other have different thermal expansion characteristics, internal stress may occur in each of the pair of thin films. The internal stress may be compressive stress or tensile stress.

Meanwhile, in the process of performing the semiconductor process, when an imbalance occurs in the internal stress of the pair of thin films in contact, a peeling or exfoliation phenomenon in which the pair of thin films are separated from a junction state may occur. Because such a peeling phenomenon corresponds to a process defect that deteriorates the quality of the integrated circuit, accurate monitoring and detection of whether the peeling phenomenon occurs is needed.

### SUMMARY

According to an embodiment of the present disclosure, a thin film peeling test structure is provided which includes a peeling risk layer disposed on a substrate, a peeling test layer disposed on the peeling risk layer, a planarized insulation layer disposed on the peeling test layer, first and second via holes penetrating the planarized insulation layer and reaching inside the peeling test layer, first and second contact vias disposed in the first and second via holes, respectively, and first and second test pads electrically connected to the first and second contact vias, respectively.

The thin film peeling test structure according to another embodiment of the present disclosure may include a peeling risk layer disposed on a substrate, a peeling test layer disposed on the peeling risk layer, a planarized insulation layer disposed on the peeling test layer, a plurality of first and second via holes penetrating the planarized insulation layer and reaching inside the peeling test layer, a plurality of first and second contact vias disposed in the plurality of first and second via holes, respectively, first and second metal line patterns disposed on the planarized insulation layer to cover the plurality of first and second contact vias, respectively, and first and second test pads electrically connected to the first and second metal line patterns, respectively. The plurality of first and second via holes may be arranged in a first direction parallel to an upper surface of the substrate.

According to another embodiment of the present disclosure a thin film peeling test method is provided which includes a test structure including a peeling risk layer, a peeling test layer, and a planarized insulation layer that are sequentially disposed on a substrate. First and second via holes may then be formed to penetrate the planarized insulation layer and to reach inside the peeling test layer. The first and second via holes may be filled with a conductive material to form first and second contact vias in the first and second via holes, respectively. First and second test pads electrically connected to the first and second contact vias, respectively, may be formed to fabricate a peeling test structure. The first and second test pads may be connected to an electrical measurement device to perform an electrical conduction test between the first and second contact vias.

These and other features and advantages of the present invention may be better understood from the following figures and detailed description of embodiments of the present disclosure.

### BRIEF DESCRIPTION OF THE DRAWINGS

FIG. 1A is a planar view illustrating a thin film peeling phenomenon that occurs during a semiconductor integration process.

FIG. 1B is a cross-sectional view of a peeling region P of FIG. 1A.

FIG. 2 is a cross-sectional view schematically illustrating a thin film peeling test structure according to an embodiment of the present disclosure.

FIG. 3 is a flowchart illustrating a thin film peeling test method according to an embodiment of the present disclosure.

FIGS. 4 to 7 are cross-sectional views schematically illustrating a thin film peeling test method according to an embodiment of the present disclosure.

FIG. 8A is a plan view schematically illustrating a thin film peeling test structure according to another embodiment of the present disclosure.

FIG. 8B is a cross-sectional view of the thin film peeling test structure of FIG. 8A taken along line I-I′.

FIG. 8C is a cross-sectional view of the thin film peeling test structure of FIG. 8A taken along line II-II′.

### DETAILED DESCRIPTION OF THE EMBODIMENTS

Hereinafter, embodiments of the present disclosure are described in detail with reference to the accompanying drawings. In the drawings, to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of additional one or more other features, numbers, steps, operations, components, elements, parts, or combinations thereof.

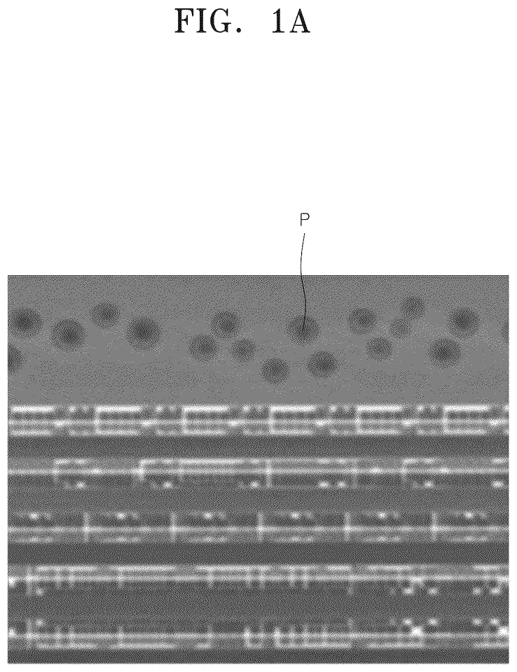

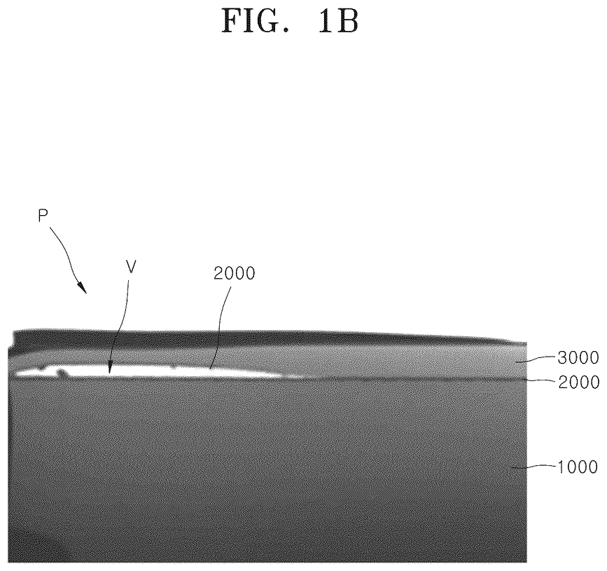

FIG. 1A is a planar photograph illustrating a thin film peeling phenomenon that occurs during a semiconductor integration process. FIG. 1B is a cross-sectional photograph of a peeling region P of FIG. 1A.

Referring to FIG. 1A, the peeling region P is shown. The peeling region P is a region in which a thin film peeling phenomenon occurs during a semiconductor integration process. Referring to FIG. 1B, when a silicon nitride layer 2000 and a silicon oxide layer 3000 are sequentially disposed and in contact with each other on a silicon substrate 1000, the silicon nitride layer 2000 may be peeled or exfoliated as shown from the silicon substrate 1000 in the peeling region P. The silicon oxide layer 3000 may cover the peeled silicon nitride layer 2000.

One of various theories or hypotheses explaining the peeling phenomenon of the silicon nitride layer 2000 is that, forming the silicon oxide layer 3000 on the silicon nitride layer 2000 in a state in which the silicon nitride layer 2000 has a different type of internal stress from the substrate 101 may increase the magnitude of the internal stress in the silicon nitride layer 2000. Referring to FIG. 1B, in the process of depositing the silicon oxide layer 3000, when the internal stress accumulated in the silicon nitride layer 2000 exceeds a predetermined threshold value, the peeling or exfoliation phenomenon in which the silicon nitride layer 2000 is separated from the substrate 101 may occur.

As shown in FIG. 1B, a void V may be formed in the peeling region P where the silicon nitride layer 2000 is separated from the substrate 101. Because the void V is difficult to heal through subsequent processes, the peeling phenomenon may cause a quality defect of the integrated circuit. Accordingly, a method of effectively determining whether the peeling phenomenon occurs during the semiconductor process may be required.

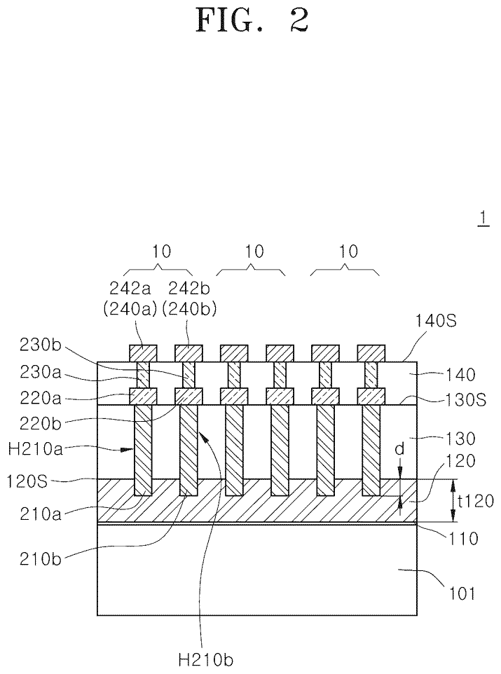

FIG. 2 is a schematic cross-sectional view illustrating a thin film peeling test structure 1 according to an embodiment of the present disclosure. The thin film peeling test structure 1 may include a plurality of test pattern structures 10.

Each of the plurality of test pattern structures 10 may include a peeling risk layer 110 disposed on a substrate 101, a peeling test layer 120 disposed on the peeling risk layer 110, a planarized insulation layer 130 disposed on the peeling test layer 120, first and second contact vias 210a and 210b that penetrate the planarized insulation layer 130 and reach inside the peeling test layer 120, and first and second test pads 242a and 242b that are electrically connected to the first and second contact vias 210a and 210b, respectively. Each of the plurality of test pattern structures 10 may be provided as a means for testing whether the peeling risk layer 110 is peeled or exfoliated from the substrate 101 when an integrated circuit process is performed.

Referring to FIG. 2, the substrate 101 may include a semiconductor material. For example, the substrate 101 may include silicon (Si), germanium (Ge), gallium arsenide (GaAs), and the like. The substrate 101 may be doped with an n-type or p-type dopant. In some embodiments, the substrate 101 may include a conductive material or an insulating material capable of being processed for semiconductor integrated circuits.

The peeling risk layer 110 and the peeling test layer 120 may be sequentially disposed on the substrate 101. The peeling risk layer 110 may refer to a thin film in which peeling or exfoliation from the substrate 101 may occur due to the internal stress. The peeling test layer 120 may refer to a thin film on which an electrical measurement is made between the first and second contact vias 210a and 210b to determine whether the peeling risk layer 110 is peeled.

The peeling risk layer 110 may have different thermal expansion characteristics from those of the substrate 101. Accordingly, when the peeling risk layer 110 is formed on the substrate 101, the peeling risk layer 110 may have a different type of internal stress from that of the substrate 101. In an embodiment, when the peeling risk layer 110 is formed on the substrate 101, the substrate 101 may have internal tensile stress, and the peeling risk layer 110 may have internal compressive stress.

In an embodiment, the peeling test layer 120 may have the same thermal expansion characteristics as the peeling risk layer 110. As an example, the substrate 101 may have internal tensile stress, and each of the peeling risk layer 110 and the peel test layer 120 may have internal compressive stress. A thickness of the peeling test layer 120 may be greater than a thickness of the peeling risk layer 110. In the process of forming the peeling test layer 120 on the peeling risk layer 110, the internal compressive stress of the peeling risk layer 110 may be increased. In an embodiment, the substrate 101 may include silicon (Si), the peeling risk layer 110 may include silicon nitride, and the peeling test layer 120 may include silicon oxide. In another embodiment, the substrate 101 may include silicon (Si), the peeling risk layer 110 may include silicon oxide, and the peeling test layer 120 may include silicon nitride.

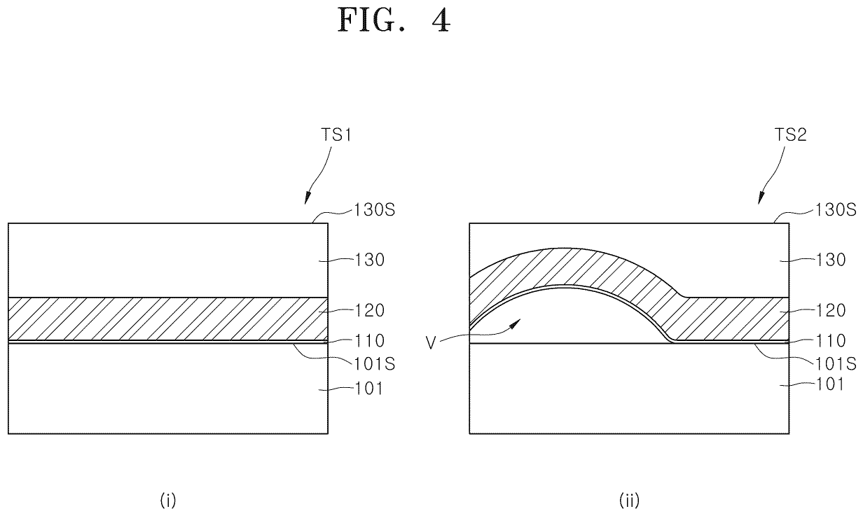

The planarized insulation layer 130 may be disposed on the peeling test layer 120. As shown in FIG. 4 to be described later, the planarized insulation layer 130 may be formed by depositing an insulation layer on the peeling test layer 120 and performing a planarization process on the insulation layer. As a result of the planarization process, an upper surface 130S of the planarized insulation layer 130 may be positioned on a plane parallel or substantially parallel to an upper surface 101S of the substrate 101.

Referring to FIG. 2, first and second via holes H210a and H210b may be formed to penetrate the planarized insulation layer 130 and to reach inside the peeling test layer 120. The first and second via holes H210a and H210b may be formed to be spaced apart from each other in a lateral direction that is substantially parallel to the upper surface 101S of the substrate 101.

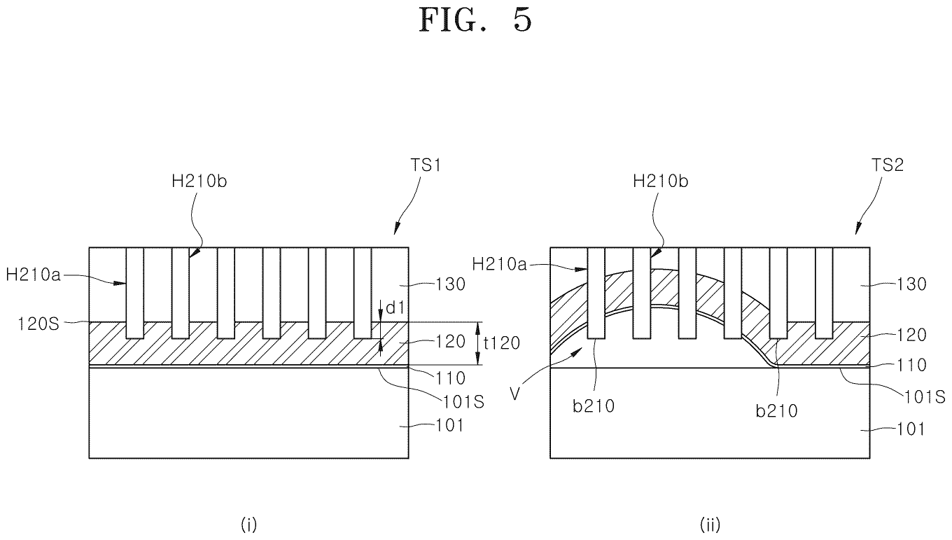

As will be described with reference to FIG. 5, each of the first and second via holes H210a and H210b may have a predetermined depth d from an upper surface 120S of the peeling test layer 120. In an embodiment, the first and second via holes H210a and H210b may be formed to reach inside the peeling test layer 120 while having the depth d corresponding to ⅓ to ½ of the thickness t120 of the peeling test layer 120 from an interface between the planarized insulation layer 130 and the peeling test layer 120 (i.e., the upper surface 120S of the peeling test layer 120).

The first and second contact vias 210a and 210b may be disposed in the first and second via holes H210a and H210b, respectively. The first and second contact vias 210a and 210b may include a conductive material filling the first and second via holes H210a and H210b, respectively. The conductive material may include, for example, tungsten (W), titanium nitride (TiN), tungsten nitride (WN), or a combination of two or more thereof.

First and second metal pattern layers 220a and 220b may be disposed on the planarized insulation layer 130 to be electrically connected to the first and second contact vias 210a and 210b, respectively. Each of the first and second metal pattern layers 220a and 220b may include, for example, copper (Cu), aluminum (Al), tungsten (W), or a combination of two or more thereof. In addition, an intermetallic insulation layer 140 covering the first and second metal pattern layers 220a and 220b may be disposed on the planarized insulation layer 130. The intermetallic insulation layer 140 may have a planarized upper surface 140S that is parallel or substantially parallel to the upper surface 101S of the substrate 101 (see for example, FIG. 4).

Referring to FIG. 2, first and second connection vias 230a and 230b may be disposed to penetrate the intermetallic insulation layer 140 and to be electrically connected to the first and second metal pattern layers 220a and 220b, respectively. Each of the first and second connection vias 230a and 230b may include, for example, tungsten (W), titanium nitride (TiN), tungsten nitride (WN), or a combination of two or more thereof.

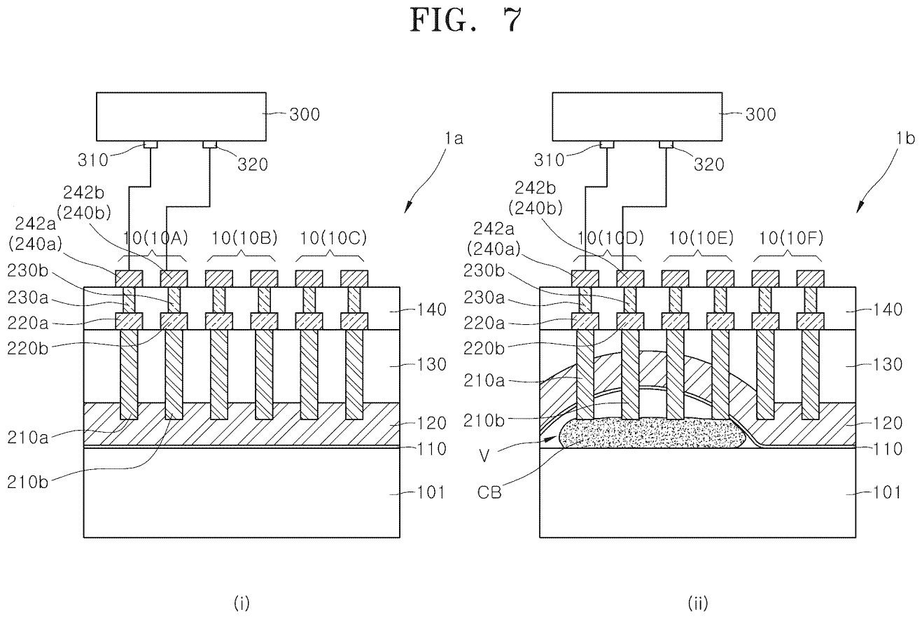

First and second upper metal pattern layers 240a and 240b electrically connected to the first and second connection vias 230a and 230b, respectively, may be disposed on the upper surface 140S of the intermetallic insulation layer 140. In addition, the first and second test pads 242a and 242b may be disposed on the upper surface 140S of the intermetallic insulation layer 140 as portions extending from the first and second upper metal pattern layers 240a and 240b, respectively. As described below with reference to FIG. 7, the first and second test pads 242a and 242b may be configured to be connected to an external electrical measurement device. An electrical resistance between the first and second contact vias 210a and 210b inside the test pattern structure 10 may be measured by applying an electrical bias to the first and second test pads 242a and 242b from the electrical measurement device.

In some embodiments, each of the first and second metal pattern layers 220a and 220b may be a metal pattern layer positioned at an uppermost layer of each of the test pattern structures 10. In this case, the first and second test pads 242a and 242 may correspond to portions of the first and second metal pattern layers 220a and 220b, and the first and second connection vias 230a and 230b and the first and second upper metal pattern layers 240a and 240b may be omitted. In addition, in some embodiments, each of the test pattern structures may further include at least one connection via and at least one metal pattern layer that are disposed on the first and second upper metal pattern layers 240a and 240b and electrically connected to the first and second upper metal pattern layers 240a and 240b, respectively. In this case, each of the first and second test pads 242a and 242 may correspond to a portion of the metal pattern layer positioned at an uppermost layer.

As described above, the thin film peeling test structure according to an embodiment of the present disclosure may include a peeling risk layer and a peeling test layer sequentially stacked on a substrate. The thin film peeling test structure may include first and second contact vias reaching inside the peeling test layer, and first and second test pads electrically connected to the first and second contact vias, respectively. Electrical resistance between the first and second contact vias positioned inside the thin film peeling test structure may be measured through an electrical bias applied to the first and second test pads from an external electrical measurement device. As will be described later, it is possible to effectively determine whether the peeling risk layer is peeled from the substrate through the measured electrical resistance.

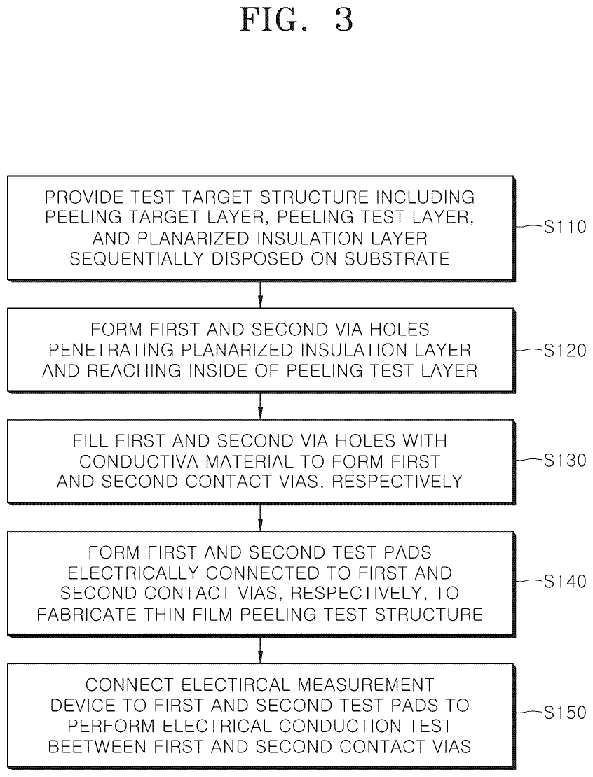

FIG. 3 is a flowchart schematically illustrating a thin film peeling test method according to an embodiment of the present disclosure. FIGS. 4 to 7 are cross-sectional views schematically illustrating a thin film peeling test method according to an embodiment of the present disclosure. The thin film peeling test method of FIGS. 4 to 7 may be performed using the thin film peeling test structure 1 described with reference to FIG. 2.

Reference numerals (i) in FIGS. 4 to 7 illustrate a peeling test process for a first test structure TS1 in which the peeling phenomenon of the peeling risk layer from the substrate has not occurred, and reference numerals (ii) in FIGS. 4 to 7 illustrate a peeling test process for a second test structure TS2 in which the peeling phenomenon of the peeling risk layer from the substrate has occurred.

Referring to operation S110 of FIG. 3 and reference numerals (i) and (ii) of FIG. 4, the first and second test structures TS1 and TS2 may be provided. Each of the first and second test structures TS1 and TS2 may include the peeling risk layer 110, the peeling test layer 120, and the planarized insulation layer 130 that are sequentially disposed on the substrate 101.

Referring to reference numerals (i) and (ii) of FIG. 4, at first, the peeling risk layer 110 may be formed on the upper surface 101S of the substrate 101, and the peeling test layer 120 may be formed on the peeling risk layer 110 in each of (i) and (ii). The thickness of the peeling test layer 120 may be greater than the thickness of the peeling risk layer 110. In an embodiment, the substrate 101 may be a silicon (Si) substrate. The peeling risk layer 110 may be a silicon nitride layer formed by chemical vapor deposition (CVD) using thermal energy. The peeling test layer 120 may be a silicon oxide layer formed by high density plasma deposition (HDPD). In the process of sequentially forming the peeling risk layer 110 and the peeling test layer 120 on the substrate 101, internal tensile stress may be generated in the substrate 101, and internal compressive stress may be generated in the peeling risk layer 110 and the peeling test layer 120. Meanwhile, in the process of forming the peeling test layer 120 by the high density plasma deposition (HDPD) method, the internal compressive stress of the peeling risk layer 110 may be increased.

Referring to reference numeral (ii) of FIG. 4, in the case of the second test structure TS2, in the process of forming the peeling test layer 120, the internal compressive stress of the peeling risk layer 110 may exceed a predetermined threshold value. Accordingly, the peeling phenomenon in which the peeling risk layer 110 is separated from the substrate 101 may occur. In the second test structure TS2, a void V may be generated in a region where the peeling risk layer 110 is peeled from the substrate 101. On the other hand, because the peeling phenomenon does not occur in the first test structure TS1 of (i) of FIG. 4, the void V is not formed in the first test structure TS1.

Next, an insulation layer may be formed on the peeling test layer 120 of the first and second test structures TS1 and TS2, and a planarization process may be performed on the insulation layer to form the planarized insulation layer 130. An upper surface 130S of the planarized insulation layer 130 may be positioned on a plane parallel or substantially parallel to the upper surface 101S of the substrate 101.

Referring to operation S120 of FIG. 3 and reference numerals (i) and (ii) of FIG. 5, the plurality of first via holes H210a and a plurality of second via holes H210b may be formed to penetrate the planarized insulation layer 130 and to reach inside the peeling test layer 120. The first and second via holes H210a and H210b may be spaced apart from each other in a direction substantially parallel to the upper surface 101S of the substrate 101.

The process of forming the first and second via holes H210a and H210b may proceed such that the first and second via holes H210a and H210b are controlled to have a predetermined depth “d” from an interface between the planarized insulation layer 130 and the peeling test layer 120 (i.e., an upper surface 120S of the peeling test layer 120), based on the first test structure TS1 shown in (i) of FIG. 5. In an embodiment, the process of forming the first and second via holes H210a and H210b may proceed by performing an etching process on the planarized insulation layer 130 and the peeling test layer 120, in which a target etching depth “d” may correspond to ⅓ to ½ of the thickness t120 of the peeling test layer 120 from the upper surface 120S of the peeling test layer 120.

Referring to reference numeral (ii) of FIG. 5, in the case of the second test structure TS2, the etching process with the target etching depth may be performed, so that some via holes among the first and second via holes H210a and H210b may reach the void V formed between the substrate 101 and the peeling risk layer 110. That is, because the peeling phenomenon of the peeling risk layer 110 from the substrate 101 has occurred, bottom surfaces b210 of some via holes of the first and second via holes H210a and H210b may be positioned inside the void V.

Meanwhile, when the target etching depth is controlled to be less than ⅓ of the thickness t120 of the peeling test layer 120 from the upper surface 120S of the peeling test layer 120, the first and second via holes H210a and H210b in the second test structure TS2 might not reach the void V. Conversely, when the target etching depth is controlled to exceed ½ of the thickness t120 of the peeling test layer 120 from the upper surface 120S of the peeling test layer 120, there may be a risk of over-etching in which the first and second via holes H210a and H210b in the first test structure TS1 penetrate the peeling test layer 120 and the peeling risk layer 110 to reach the inside of the substrate 101.

Accordingly, according to an embodiment of the present disclosure, when forming the first and second via holes H210a and H210b in the second test structure TS2, the target etching depth under the above-described condition for the planarized insulation layer 130 and the peeling test layer 120 may be determined so that the first and second via holes H210a and H210b are exposed to the void V without a process error. In addition, the target etching depth may be determined based on the first test structure TS1 in which the peeling of the peeling risk layer 110 from the substrate 101 does not occur, thereby increasing the reliability of the etching process having the target etching depth.

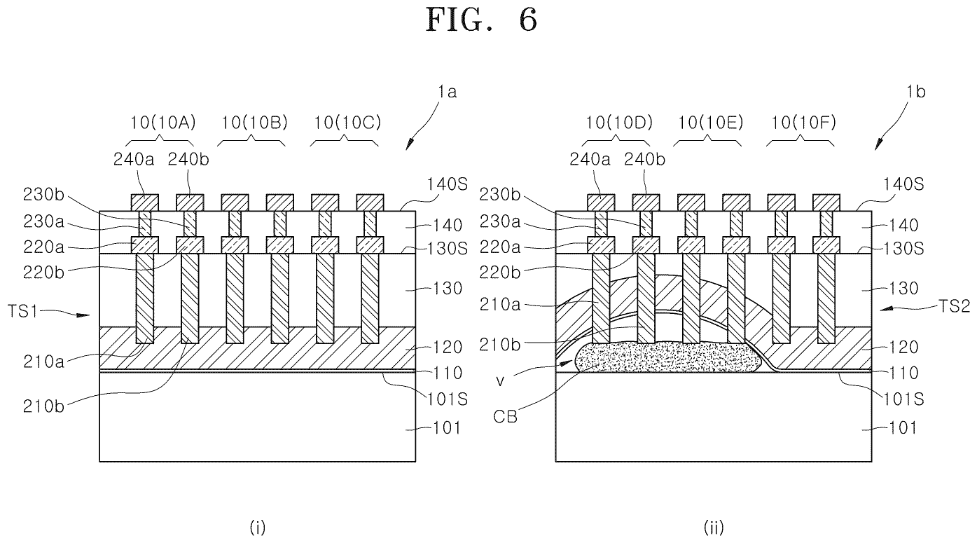

Referring to operation S130 of FIG. 3 and reference numerals (i) and (ii) of FIG. 6, the first and second via holes H210a and H210b may be filled with a conductive material to form the first and second contact vias 220a and 220b. Referring to reference numeral (ii) of FIG. 6, because some via holes among the first and second via holes H210a and H210b in the second test structure TS2 are exposed to the void V, the conductive material may be exposed in the void V to each other to form a conductive bridge CB. The conductive bridge CB may electrically connect the first and second contact vias 220a and 220b to each other. On the other hand, referring to reference numeral (i) of FIG. 6, because the first test structure TS1 does not include the void V, in the process of forming the first and second contact vias 220a and 220b, the conductive bridge CB cannot be formed.

Subsequently, the first and second metal pattern layers 220a and 220b electrically connected to the first and second contact vias 210a and 210b, respectively, may be formed on the planarized insulation layer 130. Each of the first and second metal pattern layers 220a and 220b may include, for example, copper (Cu), aluminum (Al), tungsten (W), or a combination of two or more thereof.

Subsequently, the intermetallic insulation layer 140 covering the first and second metal pattern layers 220a and 220b may be formed on the planarized insulation layer 130. The intermetallic insulation layer 140 may include, for example, oxide, nitride, oxynitride, or a combination thereof. The intermetallic insulation layer 140 may have a planarized upper surface 140S substantially parallel to the upper surface 101S of the substrate 101.

Subsequently, the first and second connection vias 230a and 230b may be formed to penetrate the intermetallic insulation layer 140 and to be electrically connected to the first and second metal pattern layers 220a and 220b, respectively. Each of the first and second connection vias 230a and 230b may include, for example, tungsten (W), titanium nitride (TiN), tungsten nitride (WN), or a combination of two or more thereof.

Subsequently, the first and second upper metal pattern layers 240a and 240b electrically connected to the first and second connection vias 230a and 230b, respectively, may be formed on the upper surface 140S of the intermetallic insulation layer 140. Each of the first and second upper metal pattern layers 240a and 240b may include, for example, copper (Cu), aluminum (Al), tungsten (W), or a combination of two or more thereof.

Referring to operation S140 of FIG. 3 and reference numerals (i) and (ii) of FIG. 6, the first and second test pads 242a and 242b extending from the first and second upper metal pattern layers 240a and 240b, respectively, may be formed on the intermetallic insulation layer 140. The first and second test pads 242a and 242b may be electrically connected to the first and second conductive vias 210a and 210b, respectively. In this case, the first metal pattern layer 220a, the first connection via 230a, and the first upper metal pattern layer 240a that electrically connect the first test pad 242a to the first conductive via 210a may constitute a first wiring. Similarly, the second metal pattern layer 220b, the second connection via 230b, and the second upper metal pattern layer 240b that electrically connect the second test pad 242b to the second conductive via 210b may constitute a second wiring.

Through the above-described processes, the first and second thin film peeling test structures 1a and 1b each including the plurality of test pattern structures 10 may be manufactured. Each of the plurality of test pattern structures 10 may include a pair of first and second contact vias 210a and 210b and a pair of test pads 242a and 242b electrically connected to a pair of first and second contact vias 210a and 210b, respectively.

Referring to reference numeral (i) of FIG. 6, the first thin film peeling test structure 1a may include first to third test pattern structures 10A, 10B, and 10C having substantially the same configuration as each other. Referring to reference numeral (ii) of FIG. 6, the second thin film peeling test structure 1b may include fourth to sixth test pattern structures 10D, 10E, and 10F having substantially the same configuration as each other. In FIG. 6, although each of the first and second thin film peeling test structures 1a and 1b is illustrated as having three test pattern structures for the convenience of description, the technical idea of the present disclosure is not necessarily limited thereto, and it is possible for each of the first and second thin film peeling test structures 1a and 1b to have various numbers of the test pattern structures.

Referring to operation S150 of FIG. 3 and reference numerals (i) and (ii) of FIG. 7, the first and second test pads 242a and 242b may be connected to the electrical measurement device 300 to perform an electrical conduction test between the first and second contact vias 210a and 210b.

Referring to reference numeral (i) of FIG. 7, in the first test pattern structure 10A of the first thin film peeling test structure 1a, the first and second test pads 242a and 242b may be connected to first and second bias terminals 310 and 320 of the electrical measurement device 300, respectively. An electrical bias may be applied to the first and second test pads 242a and 242b from the electrical measurement device 300, and thus, a voltage may be applied between the first and second contact vias 210a and 210b of the first test pattern structure 10A. Because the first and second contact vias 210a and 210b of the first test pattern structure 10A may be electrically insulated from each other within the insulating second peeling test layer 120, a high resistance may be measured between the first and second contact vias 210a and 210b. Subsequently, a high resistance may also be measured between the first and second contact vias 210a and 210b of each of the second and third test pattern structures 10B and 10C.

Referring to reference numeral (ii) of FIG. 7, in the case of the fourth test pattern structure 10D of the second thin film peeling test structure 1b, because the first and second contact vias 210a and 210b are electrically connected to each other by the conductive bridge CB, a low resistance may be measured between the first and second contact vias 210a and 210b. Similarly, a low resistance may be measured between the first and second contact vias 210a and 210b of the fifth test pattern structure 10E. On the other hand, in the case of the sixth test pattern structure 10F, because the first and second contact vias 210a and 210b are electrically insulated from each other within the insulating second peeling test layer 120, a high resistance may be measured between the first and second contact vias 210a and 210b.

As described above, according to the embodiment of the present disclosure, when the peeling phenomenon occurs in the process of forming the thin film peeling test structure, an electrical resistance between a pair of first and second contact vias may be measured as a low resistance in at least one test pattern structure 10D or 10E of the thin film peeling test structure. Accordingly, it is possible to effectively determine whether peeling occurs between the substrate and the peeling risk layer through the above-described method of measuring the electrical resistance between the pair of first and second contact vias.

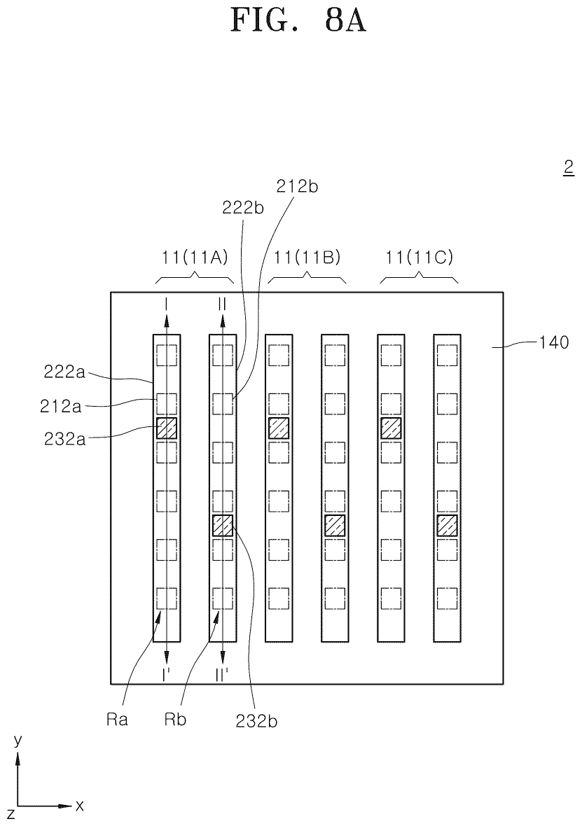

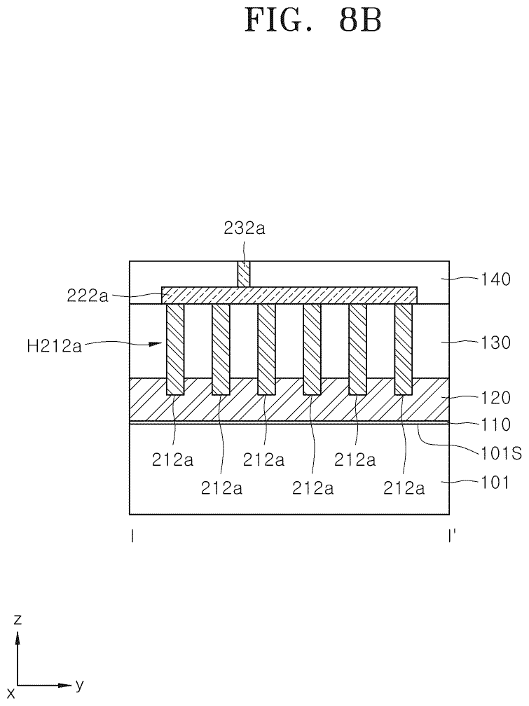

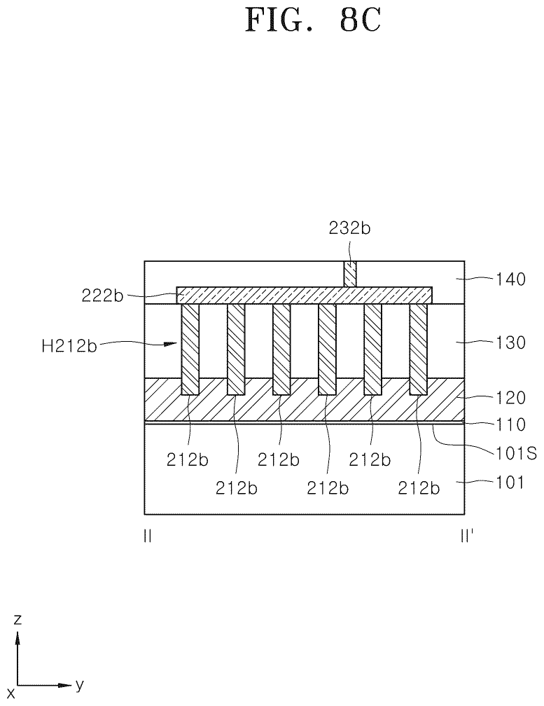

FIG. 8A is a plan view schematically illustrating a thin film peeling test structure 2 according to another embodiment of the present disclosure. FIG. 8B is a cross-sectional view of the thin film peeling test structure 2 of FIG. 8A taken along line I-I′. FIG. 8C is a cross-sectional view of the thin film peeling test structure 2 of FIG. 8A taken along line II-II′.

Referring to FIGS. 8A, 8B, and 8C, compared to the thin film peeling test structure 1 of FIG. 2, the thin film peeling test structure 2 may be differentiated from the thin film peeling test structure 1 in configurations of first and second contact vias 212a and 212b, first and second metal line patterns 222a and 222b, and the first and second intermetallic connection vias 232a and 232b.

The thin film peeling test structure 2 may include a plurality of test pattern structures 11. In an embodiment, the thin film peeling test structure 2 may include first to third test pattern structures 11A, 11B, and 11C having substantially the same configuration. Referring to FIGS. 8B and 8C, first and second via holes H212a and H212b of the first test pattern structure 11A may be arranged along one direction (e.g., the y-direction) substantially parallel to an upper surface 101S of a substrate 101 to form an array Ra of the first via holes H212a and an array Rb of the second via holes H212b. Accordingly, the first and second contact vias 212a and 212b of the first test pattern structure 11A ma be disposed in the first and second via holes H212a and H212b to constitute an array Ra of the first contact vias 212a and an array Rb of the second contact vias 212b.

A first metal line pattern 222a electrically connected to the array Ra of the first contact vias 212a may be disposed on a planarized insulation layer 130. Similarly, a second metal line pattern 222b electrically connected to the array Rb of the second contact vias 212b may be disposed on the planarized insulation layer 130.

An intermetallic insulation layer 140 covering the first and second metal line patterns 222a and 222b may be disposed on the planarized insulation layer 130. The first and second intermetallic connection vias 232a and 232b electrically connected to the first and second metal line patterns 222a and 222b, respectively, may be disposed in the intermetallic insulation layer 140.

Although not shown in FIGS. 8A, 8B, and 8C, first and second upper metal pattern layers electrically connected to the first and second intermetallic connection vias 232a and 232b may be disposed on the intermetallic insulation layer 140, and first and second test pads may be disposed as portions of the first and second metal pattern layers. Configurations of the first and second upper metal pattern layers and the first and second test pads may be substantially the same as those of the first and second upper metal pattern layers 240a and 240b and the first and second test pads 242a and 242b described above with reference to FIG. 2, respectively.

According to the embodiment of the present disclosure, a thin film peeling test method using the thin film peeling test structure 2 may apply the thin film peeling test method including operations S110 to S150 described with reference to FIG. 3.

However, in operation S120 of FIG. 3, the process of forming the first and second via holes may proceed as a process of forming the array Ra of the first via holes H212a and the array Ra of the second via holes H212b along one direction (e.g., the y-direction) substantially parallel to the upper surface 101S of the substrate 101, as shown in FIGS. 8A, 8B, and 8C.

In addition, in operation S130 of FIG. 3, forming the first and second conductive vias may be performed by filling the first and second via holes H212a and H212b with a conductive material, thereby forming the array Ra of the first contact vias 212a and the second contact vias 212b along the one direction, as shown in FIGS. 8A, 8B, and 8C.

In addition, in operation S140 of FIG. 3, forming the first and second test pads may include a process of forming the first metal line pattern 222a and the second metal line pattern 222a on the planarized insulation layer 130 to cover the array Ra of the first contact vias 212a and the array Rb of the second contact vias 212b, respectively, a process of forming the first and second intermetallic connection vias 232a and 232b on the first and second metal line patterns 222a and 222b, respectively, a process of forming the first and second upper metal pattern layers electrically connected to the first and second intermetallic connection vias 232a and 232b, respectively, and a process of forming the first and second test pads extending from the first and second upper metal pattern layers, respectively. The first test pad may be electrically connected to the array Ra of the first contact vias 212a through the first metal line pattern 222a, and the second test pad may be electrically connected to the array Rb of the second contact vias 212b through the second metal line pattern 222a.

In addition, in operation S150 of FIG. 3, the process of performing the electrical conduction test may be performed by applying electrical bias to the first and second test pads by an electrical measurement device to measure the electrical resistance between the array Ra of the first contact via 212a and the array Ra of the second contact via 212b. Accordingly, according to the electrical conduction test for the thin film peeling test structure 2 shown in FIGS. 8A, 8B and 8C, whether the peeling risk layer 110 is peeled in a wider region on the substrate 101 can be effectively determined through a resistance measurement result once, compared to the electrical conduction test for the thin film peeling test structure 1 of FIG. 2.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all distinctive features in the equivalent scope should be construed as being included in the concepts. Furthermore, the embodiments may be combined to form additional embodiments.

What is claimed is:

1. A thin film peeling test structure comprising:
a peeling risk layer disposed on a substrate;
a peeling test layer disposed on the peeling risk layer;
a planarized insulation layer disposed on the peeling test layer;
first and second via holes penetrating the planarized insulation layer and reaching inside the peeling test layer;
first and second contact vias disposed in the first and second via holes, respectively; and
first and second test pads electrically connected to the first and second contact vias, respectively.

2. The thin film peeling test structure of claim 1, further comprising a void generated between the substrate and the peeling risk layer, wherein the first and second via holes are exposed to the void.

3. The thin film peeling test structure of claim 1, further comprising:
a void generated between the substrate and the peeling risk layer; and
a conductive bridge extending inside the void from the first and second contact vias and electrically connecting the first and second contact vias to each other.

4. The thin film peeling test structure of claim 1,
wherein the substrate includes silicon (Si), and
wherein one of the peeling risk layer and the peeling test layer includes silicon nitride, and the other includes silicon oxide.

5. The thin film peeling test structure of claim 1, wherein each of the first and second via holes has a depth corresponding to ⅓ to ½ of a thickness of the peeling test layer from an interface between the planarized insulation layer and the peeling test layer, and reaches the inside of the peeling test layer.

6. The thin film peeling test structure of claim 1, further comprising at least one metal pattern and at least one connection via electrically connecting the first and second contact vias to the first and second test pads, respectively.

7. A thin film peeling test structure comprising:
a peeling risk layer disposed on a substrate;
a peeling test layer disposed on the peeling risk layer;
a planarized insulation layer disposed on the peeling test layer;
a plurality of first and second via holes penetrating the planarized insulation layer and reaching inside the peeling test layer;
a plurality of first and second contact vias disposed in the plurality of first and second via holes, respectively;
first and second metal line patterns disposed on the planarized insulation layer to cover the plurality of first and second contact vias, respectively; and
first and second test pads electrically connected to the first and second metal line patterns, respectively,
wherein the plurality of first and second via holes are arranged in a first direction parallel to an upper surface of the substrate.

8. The thin film peeling test structure of claim 7, further comprising a void generated between the substrate and the peeling risk layer,
wherein the plurality of first and second via holes are connected to the void.

9. The thin film peeling test structure of claim 7, further comprising:
a void generated between the substrate and the peeling risk layer; and
a conductive bridge extending inside the void from the first and second contact vias and electrically connecting the first and second contact vias to each other.

10. The thin film peeling test structure of claim 7, wherein each of the first and second via holes has a depth corresponding to ⅓ to ½ of a thickness of the peeling test layer from an interface between the planarized insulation layer and the peeling test layer, and
reaches the inside of the peeling test layer.

11. The thin film peeling test structure of claim 7, further comprising first and second wirings electrically connecting the first and second metal line patterns to the first and second test pads, respectively,
wherein each the first and second wirings includes at least one metal pattern layer and at least one connection via.

12. A thin film peeling test method comprising:
providing a test structure including a peeling risk layer, a peeling test layer, and a planarized insulation layer that are sequentially disposed on a substrate;
forming first and second via holes penetrating the planarized insulation layer and reaching inside the peeling test layer;
filling the first and second via holes with a conductive material to form first and second contact vias in the first and second via holes, respectively;
forming first and second test pads electrically connected to the first and second contact vias, respectively, to fabricate a peeling test structure; and
performing an electrical conduction test between the first and second contact vias by connecting the first and second test pads to an electrical measurement device.

13. The thin film peeling test method of claim 12, wherein forming the first and second via holes is controlled so that each of the first and second via holes has a depth corresponding to ⅓ to ½ of a thickness of the peeling test layer from an interface between the planarized insulation layer and the peeling test layer and reaches inside of the peeling test layer.

14. The thin film peeling test method of claim 12, wherein the test structure further includes a void formed on the substrate due to peeling of the peeling risk layer from the substrate.

15. The thin film peeling test method of claim 12, wherein when the test structure includes a void, forming the first and second via holes further includes allowing the first and second via holes to be exposed to the void.

16. The thin film peeling test method of claim 12, wherein forming the first and second contact vias further includes forming a conductive bridge electrically connecting the first and second contact vias to each other due to connection of the conductive material filling the first and second via holes, in the void.

17. The thin film peeling test method of claim 12, wherein forming the first and second via holes includes forming arrays of the first and second via holes arranged along a direction substantially parallel to an upper surface of the substrate.

18. The thin film peeling test method of claim 17, wherein forming the first and second contact vias includes filling the first and second via holes with a conductive material to form arrays of the first and second contact vias, respectively.

19. The thin film peeling test method of claim 18, wherein forming the first and second test pads includes:
forming a first metal line pattern and a second metal line pattern on the planarized insulation layer to cover the array of first contact vias and the array of second contact vias, respectively;
forming first and second intermetallic connection vias formed on the first and second metal line patterns, respectively;
forming first and second upper metal pattern layers electrically connected to the first and second intermetallic connection vias, respectively; and
forming the first and second test pads extending from the first and second upper metal pattern layers, respectively.

20. The thin film peeling test method of claim 19, wherein performing the electrical conduction test includes measuring an electrical resistance between the array of first contact vias and the array of second contact vias by applying a voltage between the first and second test pads.
